(19) United States
(12) Patent Application Publication
(10) Pub. No.: US 2007/0077678 A1
(43) Pub. Date: Apr. 5, 2007

(54) Method of fabricating image sensors

(75) Inventors: Tae-Seok Oh, Seoul (KR); Jung-Ho Park, Seoul (KR)

Correspondence Address: F. Chau & Associates, LLC, 130 Woodbury Road, Woodbury, NY, 11797, US

(73) Assignee: Samsung Electronics Co., Ltd., Suwon-si (KR)

(21) Appl. No.: 11/528,132

(22) Filed: Sep. 27, 2006

(30) Foreign Application Priority Data
Oct. 5, 2005 (KR) 10-2005-93555

(51) Int. Cl. H01L 21/00

(52) U.S. Cl. 438/60; 438/70

(57) ABSTRACT

A method of fabricating image sensors includes forming an isolation pattern in a semiconductor substrate of a first conductivity type to define a light receiving region and an active region and forming a sidewall impurity region of a second conductivity type in the edge of the light receiving region to contact the isolation pattern. The method further includes forming a photo diode in the light receiving region.

This application relies for priority upon Korean Patent Application No. 2005-93555, filed on Oct. 5, 2005, the contents of which are hereby incorporated by reference herein in their entirety.

### BACKGROUND OF THE INVENTION

1. Technical Field

The present disclosure relates to a method of fabricating complementary metal oxide silicon (CMOS) image sensors, and more particularly, to a method of fabricating CMOS image sensors that can reduce a dark current generated at an interfacial surface between a photo diode region and an isolation layer.

2. Description of the Related Art

An image sensor is a semiconductor device that converts an optical image into an electric signal. Moreover, image sensors are generally categorized as either a charge coupled device (CCD) or a CMOS image sensor. A CCD image sensor may not be easily integrated with a signal processing circuit because the CCD image sensor is generally complex to drive, consumes high power, and requires a lot of mask processes. On the other hand, the CMOS image sensor typically consumes low power and can be fabricated with a signal processing circuit through a smaller number of mask processes such that the demand for the CMOS image sensor as an advanced image sensor has increased.

The CMOS image sensor typically includes a light receiving unit, which generates signal charges using externally incident light, and a CMOS signal processing circuit, which electronically processes the signal charges generated by the light receiving unit and converts the processed signal charges into data. More specifically, the light receiving unit of the CMOS image sensor includes a photo diode for generating the signal charges. When external light is incident in the photo diode, electron-hole pairs used for the signal charges are generated in the photo diode. The signal charges are accumulated in the photo diode and transformed into an electric signal by the CMOS signal processing circuit that is electrically connected to the photo diode.

The fabrication of a CMOS image sensor comprises steps of forming an isolation pattern to define a photo diode region and an active region and forming gate patterns. The gate patterns are used as gate electrodes for reset transistors and transfer transistors. Thereafter, an ion implantation process is implemented to form a photo diode including an NPD and a PPD in the photo diode region.

To increase the integration density of a CMOS image sensor, the recent isolation pattern has been formed by means of a shallow trench isolation (STI) technique. The STI technique involves etching a semiconductor substrate using an anisotropic etching process to form a trench and filling the trench with an insulation layer. However, this STI technique may cause etching damage to an inner wall of the trench, thereby resulting in the formation of a dark current.

A dark current is generally defined as a noise signal that flows through a photosensitive device even in the case of no light, and which may deteriorate the image quality and the white defect property of an image sensor. In particular, a dark current may be increased by silicon dangling bonds, which are laid on the inner wall of the trench, and the interfacial surface between the isolation pattern and the substrate. For example, to lessen the dark current, Korean Patent Application Nos. 10-2003-0077567, 10-2003-0074445, and 10-2003-0075424 describe techniques of forming impurity regions, which have a conductivity type different from the substrate, between the isolation pattern and the photo diode region. The impurity regions prevent the isolation pattern from directly contacting the photo diode region so as to solve the difficulty of dark current.

The above-described conventional techniques include a process of forming spacers exposing the top of the photo diode region on sidewalls of the gate patterns. As is well known, the formation of the spacers includes coating a spacer layer and etching the spacer layer using an anisotropic etching process. However, as the anisotropic etching process for forming the spacers may cause etching damage to an underlying layer, the top of the photo diode region may sustain etching damage during the formation of the spacers. Considering that etching damage to the photo diode region may be another cause of the generation of a dark current, the above-mentioned conventional techniques may encounter dark current difficulties.

Thus, to reduce etching damage arising from the formation of the spacers, a photoresist pattern may be formed to cover the spacer layer over the photo diode region, and the spacer layer may be etched through an anisotropic etching process using the photoresist pattern as an etch mask. In this case, the ion implantation process for forming the impurity regions should be implemented at a higher energy so that the impurity ions can be implanted to a predetermined depth through the spacer layer. However, such elevation of ion energy makes it difficult to control the doping profile of the impurity regions.

In particular, when the impurity region is formed after the formation of the spacer, the spacer functions as an ion implantation mask during the ion implantation process for forming the impurity region. As a result, the impurity region is not formed around the gate pattern, but rather the photo diode region is brought into contact with the isolation pattern.

Thus, there is a need for a method of fabricating image sensors that can lessen a dark current generated at an interfacial surface between a photo diode region and an isolation pattern.

### SUMMARY OF THE INVENTION

The exemplary embodiments of the present invention provides a method of fabricating image sensors that can lessen a dark current generated at an interfacial surface between a photo diode region and an isolation pattern.

The exemplary embodiments of the present invention also provide a method of fabricating image sensors that can minimize etching damage of a photo diode region and prevents the photo diode region from directly contacting an isolation layer.

In accordance with an exemplary embodiment of the present invention, a method of fabricating an image sensor is provided. The method includes forming an isolation pattern in a semiconductor substrate of a first conductivity type to define a light receiving region and an active region, forming a sidewall impurity region of a second conductivity type in the edge of the light receiving region to contact the isolation pattern and forming a photo diode in the light receiving region.

The forming of the sidewall impurity region may include forming a first mask pattern to expose the edge of the light receiving region and performing a first ion implantation process using the first mask pattern as an ion implantation mask to form the sidewall impurity region in the edge of the light receiving region. Herein, the first mask pattern may cover the center of the light receiving region. As a result, the sidewall impurity region may not be formed in the center of the light receiving region.

In other exemplary embodiments of the present invention, the isolation pattern may be formed such that the light receiving region is connected to the active region, and the first mask pattern is formed over a region where the light receiving region is connected to the active region. As a result, the sidewall impurity region may not be formed in the active region. The first mask pattern may extend from the isolation pattern to the region where the light receiving region is connected to the active region and the center of the light receiving region. As a result, the sidewall impurity region may not be formed in the entire edge of the light receiving region.

In still other exemplary embodiments of the present invention, the first ion implantation process may include several ion implantation operations using the first mask pattern as an ion implantation mask. In this case, the ion implantation operations may be performed under different ion energy conditions to control the doping profile of the sidewall impurity region.

The forming of the photo diode may include forming a higher impurity region of a second conductivity type in a higher region of the light receiving region and forming a lower impurity region of a first conductivity type in a lower region of the light receiving region. Herein, the sidewall impurity region may be formed between the lower impurity region and the isolation pattern.

In still other exemplary embodiments of the present invention, the forming of the higher impurity region may include forming a second mask pattern on the semiconductor substrate, the second mask pattern having an opening exposing the light receiving region and performing a second ion implantation process using the second mask pattern as an ion implantation mask to form the higher impurity region in the light receiving region. In this case, the second ion implantation process may be performed under the condition of energy lower than a third ion implantation process for forming the lower impurity region. Further, the forming of the lower impurity region may include forming a third mask pattern on the semiconductor substrate, the third mask pattern having an opening exposing the light receiving region and performing a third ion implantation process using the third mask pattern as an ion implantation mask. In this case, the opening of the third mask pattern may be formed apart from the isolation pattern so that the lower impurity region is formed in the center of the light receiving region. The opening of the third mask pattern may be spaced a predetermined distance apart from the sidewall impurity region.

In still other exemplary embodiments of the present invention, before forming the photo diode, gate patterns crossing over the active region may be further formed. After forming the photo diode, a fourth mask pattern covering the light receiving region may be formed, and a fourth ion implantation process may be performed using the fourth mask pattern and the gate patterns as ion implantation masks. Thus, a lightly doped region may be formed.

In other exemplary embodiments of the present invention, after forming the photo diode, a spacer insulation layer may be formed over the semiconductor substrate where the photo diode is formed. A fifth mask pattern covering the light receiving region may be formed on the spacer insulation layer. The spacer insulating layer may be etched through an anisotropic etching process using the fifth mask pattern as an etch mask to form a spacer on a sidewall of the gate pattern. Afterwards, a fifth ion implantation process may be performed using the fifth mask pattern, the spacer, and the gate pattern as ion implantation masks to form a heavily doped region in the active region.

In further exemplary embodiments of the present invention, the sidewall impurity region may be formed before forming the photo diode, the gate pattern, and the spacer. Also, the first conductivity type may be an n type, and the second conductivity type may be a p type.

### BRIEF DESCRIPTION OF THE DRAWINGS

Exemplary embodiments of the present invention can be understood in more detail from the following description taken in conjunction with the accompanying drawings, in which:

FIG. 1 is a plan view illustrating a method of fabricating an image sensor according to an exemplary embodiment of the present invention; and

FIGS. 2 through 8 are cross sectional views illustrating a method of fabricating an image sensor according to an exemplary embodiment of the present invention.

### DETAILED DESCRIPTION OF THE EXEMPLARY EMBODIMENTS

Reference will now be made in detail to the exemplary embodiments of the present invention, examples of which are illustrated in the accompanying drawings. However, the present invention is not limited to the exemplary embodiments illustrated hereinafter. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their detailed description will be omitted for conciseness.

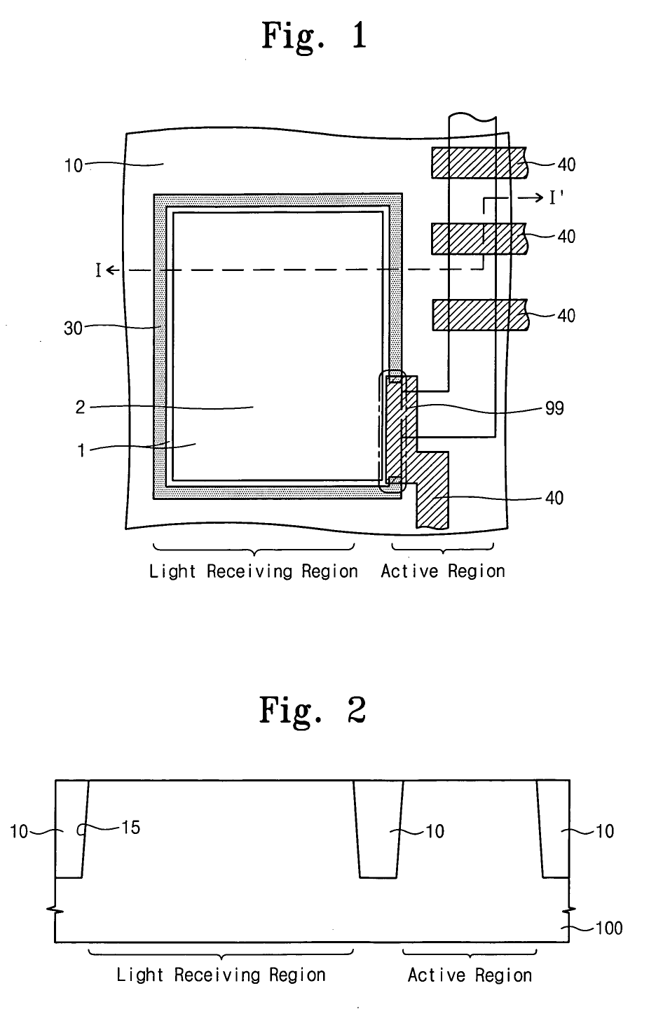

FIG. 1 is a plan view illustrating a method of fabricating an image sensor according to an exemplary embodiment of the present invention, and FIGS. 2 through 8 are cross sectional views illustrating a method of fabricating an image sensor according to an exemplary embodiment of the present invention.

Referring to FIGS. 1 and 2, an isolation pattern 10 is formed in a semiconductor substrate 100 to define an active region and a light receiving region. The active region and the light receiving region are connected to each other in a predetermined position so that signal charges accumulated in the light receiving region can be transferred to a signal processing circuit.

The formation of the isolation pattern 10 includes forming a trench mask pattern on the semiconductor substrate 100 and etching anisotropically the semiconductor substrate 100 using the trench mask pattern as an etch mask. Thus, trenches 15 defining the active region and the light receiving region are formed around the trench mask pattern. As a result, the active region and the light receiving region are provided under the trench mask pattern. Thereafter, an isolation layer is formed to fill the trenches 14 and planarized by etching until the top of the trench mask pattern is exposed, thus completing the isolation pattern 10. Then, the trench mask pattern is removed to expose the tops of the active region and the light receiving region.

On the other hand, the formation of the isolation layer may further include forming a silicon oxide layer on an inner wall of the trench 15 using a thermal oxidation process. During the thermal oxidation process, etching damage arising from the anisotropic etching process for forming the trench 15 can be cured. Considering that etching damage inflicted on the sidewall of the trench 15 is one cause of a dark current, the thermal oxidation process is beneficial in improving the dark current characteristic of image sensors.

In addition, the formation of the isolation layer may further include forming a liner layer on the inner wall of the trench 15. For example, the liner layer may be a silicon nitride layer obtained using a chemical vapor deposition (CVD) technique. The liner layer prevents diffusion of contaminants into the light receiving region or the active region during the formation of the isolation layer or a subsequent process. The use of the liner layer, along with the silicon oxide layer obtained through the thermal oxidation process, is beneficial for improving the dark current characteristic of the image sensors.

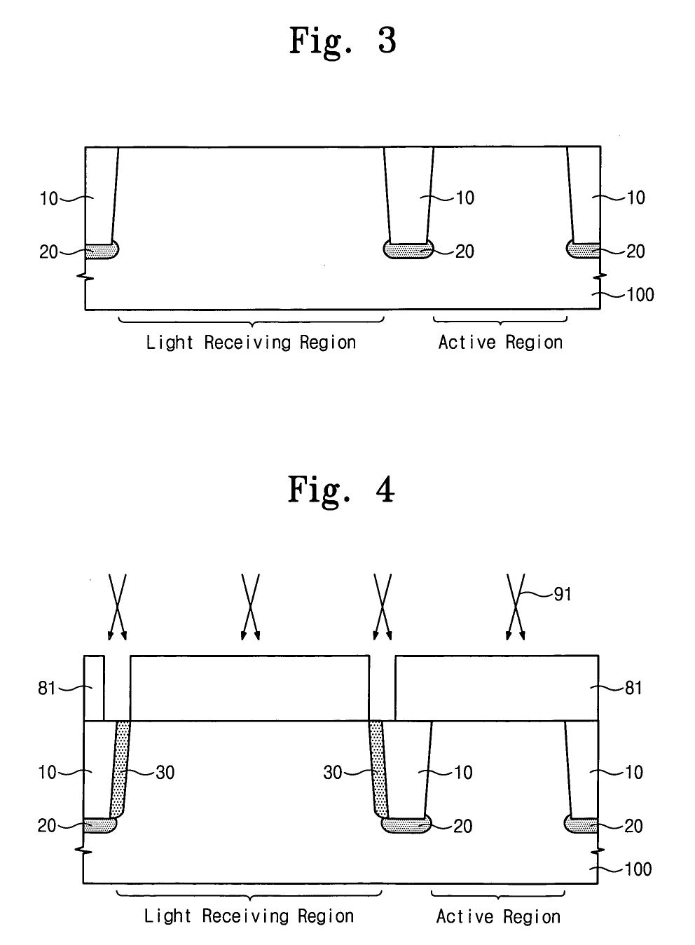

Referring to FIGS. 1 and 3, a well ion implantation process is performed on the resultant structure where the isolation pattern 10 is formed. As is well known, a CMOS image sensor includes an n-metal oxide semiconductor field effect transistor (NMOSFET) and a p-metal oxide semiconductor field effect transistor (PMOSFET). Thus, regions of different conductivities should be formed in the semiconductor substrate 100 to fabricate the CMOS image sensor. By virtue of the foregoing well ion implantation process, each region of the semiconductor substrate 100 can have different conductivities and different impurity concentrations depending on their positions. For this, the well ion implantation process may include several ion implantation operations performed under different conditions.

Also, the well ion implantation process may further include locally forming predetermined impurity regions in the semiconductor substrate 100 to improve the operating-characteristic of the image sensor. For example, a subsidiary impurity region may be formed under the isolation pattern 10 through the well ion implantation process as shown in FIG. 3. The subsidiary impurity region 20 may be formed with the same conductivity type as the semiconductor substrate 100.

Referring to FIGS. 1 and 4, after performing the well ion implantation process, a first mask pattern 81 is formed on the semiconductor substrate 100 to expose the edge of the light receiving region. Afterwards, a first ion implantation process 91 is implemented using the first mask pattern 81 as an ion implantation mask, thereby forming a sidewall impurity region 30 in the edge of the light receiving region. In this case, the first ion implantation process uses impurity ions of a conductivity type (e.g., n type) different from the semiconductor substrate 100 such that the sidewall impurity region 30 has a conductivity type different from the semiconductor substrate 100. Then, the first mask pattern 81 is removed to expose the top of the semiconductor substrate 100.

According to exemplary embodiments of the present invention, the first mask pattern 81 selectively exposes only the edge of the light receiving region. Thus, the center of the light receiving region is not exposed by the first mask pattern 81. Further, a region 99 where the light receiving region is connected to the active region may not be exposed by the first mask pattern 81. In other words, the first mask pattern 81 extends from the isolation pattern 10 to the region where the light receiving region is connected to the active region and the center of the light receiving region. As a result, as shown in FIG. 1, the sidewall impurity region 30 is not formed in the entire edge of the light receiving region but disconnected at the region 99 where the light receiving region is connected to the active region.

In one exemplary embodiment, the first ion implantation process 91 may include several ion implantation operations performed under different energy conditions. By controlling the energy conditions of the ion implantation operations, the sidewall impurity region 30 may be formed with a desired doping profile (e.g., impurity concentration relative to depth).

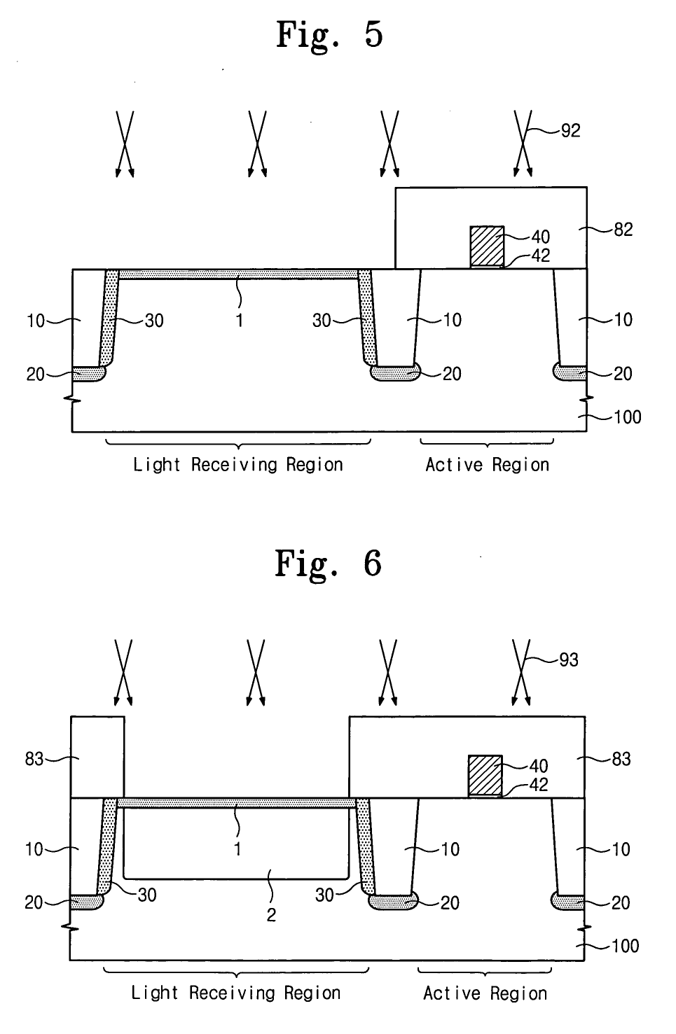

Referring to FIGS. 1 and 5, gate patterns 40 are provided across the active region.

The gate patterns 40 may form gate electrodes of a transfer transistor for transferring signal charges generated in the light receiving region to a signal processing circuit, a reset transistor, a selection transistor, and an access transistor. Before forming the gate pattern 40, a gate insulation layer 42 is formed between the gate pattern 40 and the active region. The gate insulation layer 42 may be a silicon oxide layer obtained through a thermal oxidation process.

Subsequently, on the resultant structure where the gate patterns 40 are settled, a second mask pattern 82 is formed to expose the light receiving region. A second ion implantation process 92 is carried out using the second mask pattern 82 as an ion implantation mask, thereby forming a higher impurity region 1 in a higher region of the light receiving region. In this case, the second ion implantation process 92 uses impurity ions of a conductivity type e.g., n type) different from the semiconductor substrate such that the higher impurity region 1 has a conductivity type different from the semiconductor substrate 100.

Here, the higher impurity region 1 may be connected with the sidewall impurity region 30. Thereafter, the second mask pattern 82 is removed to expose the top of the semiconductor substrate 100 on which the gate pattern 40 is laid.

Referring to FIGS. 1 and 6, on the resultant structure where the higher impurity region 30 is formed, a second mask pattern 83 is provided to expose the center of the light receiving region. Afterwards, a third ion implantation process 93 is implemented using the third mask pattern 83 as an ion implantation mask to form a lower impurity region 2 in a lower region of the light receiving region. In this case, the third ion implantation process uses impurity ions of the same conductivity type (e.g., p type) as the semiconductor substrate 100 such that the lower impurity region 2 has the same conductivity type as the semiconductor substrate 100. Then, the third mask pattern 83 is removed to expose the top of the semiconductor substrate 100 on which the gate pattern 40 is formed.

As mentioned above, the third mask pattern 83 may be formed to expose the center of the light receiving region to solve the conventional difficulty of a dark current arising from the contact between a photo diode and an isolation layer. However, according to the exemplary embodiments of the present invention, the higher impurity region 2 does not directly contact the isolation pattern 10 because the sidewall impurity region 30 is interposed between the lower impurity region 2 and the isolation pattern 10. As a result, the distance between the lower impurity region 2 and the isolation pattern 10 can be reduced. Consequently, the image sensor according to the exemplary embodiments of the present invention can increase the area of the photo diode that generates signal charges.

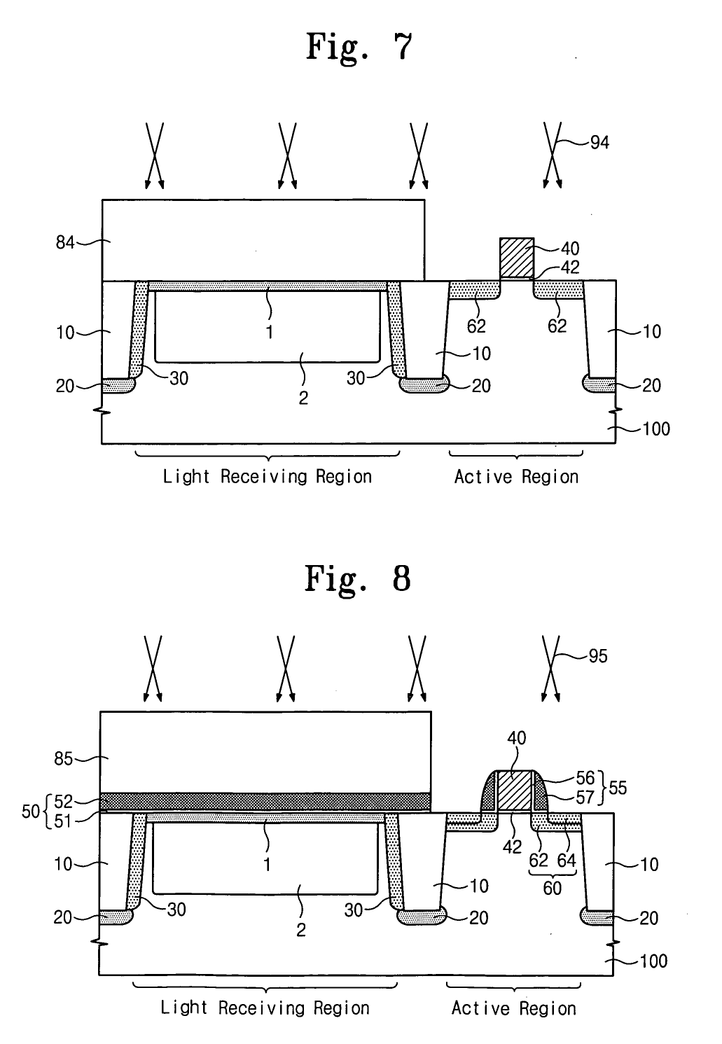

Referring to FIGS. 1 and 7, on the resultant structure where the lower impurity region 2 is formed, a fourth mask pattern 84 is provided to cover the light receiving region and expose the active region. Thereafter, a fourth ion implantation process 94 is carried out using the fourth mask pattern 84 and the gate pattern 40 as ion implantation masks, so that a lightly doped region 62 is formed in the active region around the gate pattern 40. In this case, the fourth ion implantation process 94 uses impurity ions (e.g., n type) different from the semiconductor substrate 100 such that the lightly doped region 62 has a conductivity type different from the semiconductor substrate 100. Then, the fourth mask pattern 84 is removed.

Referring to FIGS. 1 and 8, a spacer insulation layer 50 is provided on the resultant structure where the lightly doped region 62 is formed. The spacer insulation layer 50 may be formed of, for example, at least one selected from the group consisting of a silicon oxide layer, a silicon nitride layer, and a silicon oxynitride layer. In one exemplary embodiment, the spacer insulation layer 50 may include a lower spacer layer 51 and a higher spacer layer 52 that are stacked sequentially. The higher spacer layer 52 may be a silicon nitride layer, and the lower spacer layer 51 may be a silicon oxide layer so as to reduce stress that is applied to the semiconductor substrate 100 by the higher spacer layer 52.

Subsequently, a fifth mask pattern 85 is formed over the spacer insulation layer 50 to cover the light receiving region and expose the active region. The spacer insulation layer 50 is etched using an anisotropic etching process using the fifth mask pattern 85 as an etch mask until the top of the semiconductor substrate 100 is exposed. Thus, a spacer 55 is formed on a sidewall of the gate pattern 40 in the active region. In the above-described exemplary embodiment, the spacer 55 includes a lower spacer 56 and a higher spacer 57. The lower spacer 56 is formed of a silicon oxide layer, and the higher spacer 57 is formed of a silicon nitride layer.

Afterwards, a fifth ion implantation process 95 is implemented using the fifth mask pattern 85, the spacer 55, and the gate pattern 40 as ion implantation masks. Thus, a heavily doped region 64 is formed in the active region around the gate pattern 40. In this case, the fifth ion implantation process 95 uses impurity ions of a conductivity type (e.g., n type) from the semiconductor substrate 100 such that the heavily doped region 64 has a conductivity type different from the semiconductor substrate 100. The fifth ion implantation process 95 is carried out under the condition of an impurity concentration higher than the fourth ion implantation process 94. Then, the fifth mask pattern 85 is removed to expose the top of the spacer insulation layer 50 in the light receiving region.

According to the exemplary embodiments of the present invention as explained thus far, the sidewall impurity region is interposed between the photo diode (esp., the lower impurity region) and the isolation pattern, and the sidewall impurity region exhibits a conductivity type different from the lower impurity region. Thus, noise charges generated when the lower impurity region directly contacts the isolation pattern recombine in the sidewall impurity region. As a result, the image sensor according to the exemplary embodiments of the present invention can improve with respect to preventing the occurrence of a dark current.

Furthermore, according to the exemplary embodiments of the present invention, the sidewall impurity region is formed before formation of the spacer. Therefore, the sidewall impurity region can be provided without causing the spacer to act as an ion implantation mask. Consequently, the exemplary embodiments of the present invention can overcome the conventional difficulty of controlling the doping profile of the sidewall impurity region. Especially, the exemplary embodiments of the present invention are free from another difficulty of the conventional art where the sidewall impurity region is not formed under the spacer, more specifically, the case where the lower impurity region comes into contact with the isolation pattern under the spacer.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of fabricating an image sensor, comprising:
forming an isolation pattern in a semiconductor substrate of a first conductivity type to define a light receiving region and an active region;
forming a sidewall impurity region of a second conductivity type in the edge of the light receiving region to contact the isolation pattern; and
forming a photo diode in the light receiving region.

2. The method of claim 1, wherein the forming of the sidewall impurity region comprises:
forming a first mask pattern to expose the edge of the light receiving region; and
performing a first ion implantation process using the first mask pattern as an ion implantation mask to form the sidewall impurity region in the edge of the light receiving region,
wherein the first mask pattern covers the center of the light receiving region to prevent the sidewall impurity region from being formed in the center of the light receiving region.

3. The method of claim 2, wherein the isolation pattern is formed such that the light receiving region is connected to the active region,
and the first mask pattern is formed over a region where the light receiving region is connected to the active region so that the first mask pattern prevents the sidewall impurity region from being formed in the active region.

4. The method of claim 3, wherein the first mask pattern extends from the isolation pattern to the region where the light receiving region is connected to the active region and the center of the light receiving region, to prevent the sidewall impurity region from being formed in the entire edge of the light receiving region.

5. The method of claim 2, wherein the first ion implantation process includes several ion implantation operations using the first mask pattern as an ion implantation mask,
wherein the ion implantation operations are performed under different ion energy conditions.

6. The method of claim 1, wherein the forming of the photo diode comprises:
forming a higher impurity region of a second conductivity type in a higher region of the light receiving region; and
forming a lower impurity region of a first conductivity type in a lower region of the light receiving region,
wherein the sidewall impurity region is formed between the lower impurity region and the isolation pattern.

7. The method of claim 6, wherein the forming of the higher impurity region comprises:
forming a second mask pattern on the semiconductor substrate, the second mask pattern having an opening exposing the light receiving region; and
performing a second ion implantation process using the second mask pattern as an ion implantation mask to form the higher impurity region in the light receiving region,
wherein the second ion implantation process is performed under the condition of energy lower than a third ion implantation process for forming the lower impurity region.

8. The method of claim 6, wherein the forming of the lower impurity region comprises:
forming a third mask pattern on the semiconductor substrate, the third mask pattern having an opening exposing the light receiving region; and
performing a third ion implantation process using the third mask pattern as an ion implantation mask,
wherein the opening of the third mask pattern is formed apart from the isolation pattern so that the lower impurity region is formed in the center of the light receiving region.

9. The method of claim 8, wherein the opening of the third mask pattern is spaced a predetermined distance apart from the sidewall impurity region.

10. The method of claim 1, before forming the photo diode, further comprising forming gate patterns crossing over the active region.

11. The method of claim 10, after forming the photo diode, further comprising:
forming a fourth mask pattern covering the light receiving region; and
performing a fourth ion implantation process using the fourth mask pattern and the gate patterns as ion implantation masks to form a lightly doped region in the active region.

12. The method of claim 10, after forming the photo diode, further comprising:
forming a spacer insulation layer on the semiconductor substrate where the photo diode is formed;
forming a fifth mask pattern covering the light receiving region on the spacer insulation layer;
anisotropically etching the spacer insulating layer using the fifth mask pattern as an etch mask to form a spacer on a sidewall of the gate pattern; and
performing a fifth ion implantation process using the fifth mask pattern, the spacer, and the gate pattern as ion implantation masks to form a heavily doped region in the active region.

13. The method of claim 12, wherein the sidewall impurity region is formed before forming the photo diode, the gate pattern, and the spacer.

14. The method of claim 12, wherein the spacer insulation layer is formed of at least one selected from the group consisting of a silicon nitride layer, a silicon oxide layer, and a silicon oxynitride layer.

15. The method of claim 1, wherein the first conductivity type is an n-type, and the second conductivity type is a p-type.

16. A method of fabricating an image sensor, comprising:
forming an isolation pattern in a semiconductor substrate of a first conductivity type to define a light receiving region and an active region and wherein the isolation pattern is formed such that the light receiving region is connected to the active region;
forming a first mask pattern to expose the edge of the light receiving region and wherein the first mask pattern is formed over a region where the light receiving region is connected to the active region, and wherein the first mask pattern extends from the isolation pattern to the region where the light receiving region is connected to the active region and the center of the light receiving region;
performing a first ion implantation process using the first mask pattern as an ion implantation mask to form a sidewall impurity region in the edge of the light receiving region, wherein the first mask pattern covers the center of the light receiving region; and
forming a photo diode in the light receiving region by forming a higher impurity region of a second conductivity type in a higher region of the light receiving region and forming a lower impurity region of a first conductivity type in a lower region of the light receiving region, wherein the sidewall impurity region is formed between the lower impurity region and the isolation pattern.

17. The method of claim 16, wherein the forming of the higher impurity region comprises:
forming a second mask pattern on the semiconductor substrate, the second mask pattern having an opening exposing the light receiving region; and
performing a second ion implantation process using the second mask pattern as an ion implantation mask to form the higher impurity region in the light receiving region,
wherein the second ion implantation process is performed under the condition of energy lower than a third ion implantation process for forming the lower impurity region.

18. The method of claim 16, wherein the forming of the lower impurity region comprises:
forming a third mask pattern on the semiconductor substrate, the third mask pattern having an opening exposing the light receiving region; and
performing a third ion implantation process using the third mask pattern as an ion implantation mask,
wherein the opening of the third mask pattern is formed apart from the isolation pattern so that the lower impurity region is formed in the center of the light receiving region.

19. The method of claim 16, further comprising before forming the photo diode, forming gate patterns crossing over the active region and then after forming the photo diode forming a fourth mask pattern covering the light receiving region; and
performing a fourth ion implantation process using the fourth mask pattern and the gate patterns as ion implantation masks to form a lightly doped region in the active region.

20. The method of claim 16, further comprising before forming the photo diode, forming gate patterns crossing over the active region and then after forming the photo diode forming a spacer insulation layer on the semiconductor substrate where the photo diode is formed;
forming a fifth mask pattern covering the light receiving region on the spacer insulation layer;
anisotropically etching the spacer insulating layer using the fifth mask pattern as an etch mask to form a spacer on a sidewall of the gate pattern; and
performing a fifth ion implantation process using the fifth mask pattern, the spacer, and the gate pattern as ion implantation masks to form a heavily doped region in the active region.
